(19) United States
(12) Patent Application Publication
(10) Pub. No.: US 2024/0214693 A1
(43) Pub. Date: Jun. 27, 2024

(54) MACROSCOPIC REFRACTING LENS IMAGE SENSOR

(71) Applicant: QUALCOMM Incorporated, San Diego, CA (US)

(72) Inventors: Edwin Chongwoo PARK, San Diego, CA (US); Ravi Shankar KADAMBALA, Hyderabad (IN); Bapineedu Chowdary GUMMADI, Hyderabad (IN)

(21) Appl. No.: 18/436,896

(22) Filed: Feb. 8, 2024

Related U.S. Application Data
(62) Division of application No. 17/360,547, filed on Jun. 28, 2021, now abandoned.

(51) Int. Cl. H04N 23/84; G02B 1/00; G02B 3/00; H01L 27/146; H04N 23/11

(52) U.S. Cl. CPC H04N 23/84; G02B 1/002; G02B 3/0006; H01L 27/14627; H04N 23/11

(57) ABSTRACT

At least one feature pertains to an image sensor having an array of pixels with a configuration that includes a first pixel type configured to detect red light, a second pixel type configured to detect green light, a third pixel type configured to detect blue light and a fourth pixel type configured to detect green light and an array of lenses overlaying the array of pixels that comprises a first lens type, a second lens type, a third lens type and a fourth lens type where the first lens type is configured to pass red light and refract blue light and green light, the second lens type is configured to pass green light and refract blue light and red light, the third lens type is configured to pass blue light and refract red light and green light, and the fourth lens type is configured to pass green light and refract blue light and red light.

### CROSS-REFERENCE TO RELATED APPLICATION

The present Application for Patent is a divisional of U.S. patent application Ser. No. 17/360,547, entitled “MACROSCOPIC REFRACTING LENS IMAGE SENSOR,” filed Jun. 28, 2021, assigned to the assignee hereof, and expressly incorporated herein by reference in its entirety.

### BACKGROUND OF THE DISCLOSURE

### 1. Field of the Disclosure

Aspects of the disclosure relate generally to image sensors.

### 2. Description of the Related Art

Currently, many mobile devices have digital cameras that allow the users of mobile devices to take pictures or videos. Lately, certain mobile devices may have an in-display digital camera that allows for unbroken display that does not have a notch or hole-punch for a camera. In addition, such in-display camera does not need a motorized mechanism for a pop-up camera module. Both in-display cameras and regular non-display cameras for mobile devices employ Bayer filters and image sensors to captures images. The image sensors have photosensors that capture the intensity of light hitting the photosensors, and the Bayer filters filter out certain wavelength(s) of the light to capture the color information of the light hitting the image sensors.

Basically, the image sensors are overlaid with a “color filter array” that consists of many tiny microfilters that cover the pixels in the image sensors. Typically, the Bayer filter is used as the “color filter array”. Thus, the Bayer filter is a microfilter overlay for image sensors that allows for the capture of the color information. The Bayer filter uses a mosaic pattern of two parts green, one part red, and one part blue to interpret the color information arriving at the photo sensor.

However, the Bayer filter may create certain issues for the image sensors by filtering out up to 80% of the photons going through the filter. For example, in an in-display digital camera, the light hitting the display may lose more than 80% of the photons, and the Bayer filter behind the display may filter out 80% of the remaining photons. Thus, for an in-display camera, the image sensor may only receive 5-10% of the original photons in the light. Consequently, the lack of photons received by the image sensor may prevent a production of high quality image.

Accordingly, there is a need for image sensors that allow for more accurate production of the captured image by allowing the image sensors to receive greater amount of photons.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In an aspect, a method of fabricating an image sensor, the method comprising: assembling an array of pixels comprising at least one configuration that includes a first pixel type configured to detect red light, a second pixel type configured to detect green light, a third pixel type configured to detect blue light and a fourth pixel type configured to detect green light; and overlaying an array of lenses over the array of pixels, the array of lenses comprising a first lens type, a second lens type, a third lens type and a fourth lens type, wherein: the first lens type is configured to pass red light and refract blue light and green light, the second lens type is configured to pass green light and refract blue light and red light, the third lens type is configured to pass blue light and refract red light and green light, and the fourth lens type is configured to pass green light and refract blue light and red light.

In another aspect, a method of fabricating an image sensor, the method comprising: assembling a plurality of concentric pixels, the plurality of concentric pixels comprising a first pixel type configured to detect red light, a second pixel type configured to detect green light, a third pixel type configured to detect blue light and a fourth pixel type configured to detect infrared light; and overlaying a lens over the plurality of concentric pixels, wherein the lens refracts red light onto the first pixel type, refracts green light onto the second pixel type, refracts blue light onto the third pixel type and passes infrared light onto the fourth pixel type.

In an aspect, an image sensor comprises: an array of pixels, the array of pixels comprising at least one configuration that includes a first pixel type configured to detect red light, a second pixel type configured to detect green light, a third pixel type configured to detect blue light and a fourth pixel type configured to detect green light; and an array of lenses overlaying the array of pixels, the array of lenses comprising a first lens type, a second lens type, a third lens type and a fourth lens type, wherein: the first lens type is configured to pass red light and refract blue light and green light, the second lens type is configured to pass green light and refract blue light and red light, the third lens type is configured to pass blue light and refract red light and green light, and the fourth lens type is configured to pass green light and refract blue light and red light.

In another aspect, an image sensor comprises: a plurality of concentric pixels, the plurality of concentric pixels comprising a first pixel type configured to detect red light, a second pixel type configured to detect green light, a third pixel type configured to detect blue light and a fourth pixel type configured to detect infrared light; and a lens overlaying the plurality of concentric pixels, wherein the lens refracts red light onto the first pixel type, refracts green light onto the second pixel type, refracts blue light onto the third pixel type and passes infrared light onto the fourth pixel type.

In an aspect, an image sensor comprises: means for detecting lights, the means for detecting lights comprising at least one configuration that includes a first pixel type configured to detect red light, a second pixel type configured to detect green light, a third pixel type configured to detect blue light and a fourth pixel type configured to detect green light; and means for refracting lights, the means for refracting lights comprising a first lens type, a second lens type, a third lens type and a fourth lens type, wherein: the first lens type is configured to pass red light and refract blue light and green light, the second lens type is configured to pass green light and refract blue light and red light, the third lens type is configured to pass blue light and refract red light and green light, and the fourth lens type is configured to pass green light and refract blue light and red light.

In another aspect, an image sensor comprises: means for detecting lights, the means for detecting lights comprising a plurality of concentric pixels, the plurality of concentric pixels including a first pixel type configured to detect red light, a second pixel type configured to detect green light, a third pixel type configured to detect blue light and a fourth pixel type configured to detect infrared light; and means for refracting lights, the means for refracting lights comprising a lens overlaying the plurality of concentric pixels, wherein the lens refracts red light onto the first pixel type, refracts green light onto the second pixel type, refracts blue light onto the third pixel type and passes infrared light onto the fourth pixel type.

Other objects and advantages associated with the aspects disclosed herein will be apparent to those skilled in the art based on the accompanying drawings and detailed description.

### BRIEF DESCRIPTION OF THE DRAWINGS

The accompanying drawings are presented to aid in the description of various aspects of thereof.

FIG. 1 illustrates an exemplary implementation of a mobile device with an exemplary image sensor, according to aspects of the disclosure.

FIG. 2A-2E illustrates an exemplary image sensor, according to aspects of the disclosure.

FIG. 3 illustrates another exemplary image sensor, according to aspects of the disclosure.

FIG. 4 illustrates an exemplary implementation of a wireless communication device with an exemplary image sensor according to aspects of the disclosure.

FIGS. 5A-5B illustrate flowcharts corresponding to one or more methods of fabricating an image sensor, according to various aspects of the disclosure.

### DETAILED DESCRIPTION

Aspects of the disclosure are provided in the following description and related drawings directed to various examples provided for illustration purposes. Alternate aspects may be devised without departing from the scope of the disclosure. Additionally, well-known elements of the disclosure will not be described in detail or will be omitted so as not to obscure the relevant details of the disclosure.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage or mode of operation.

Those of skill in the art will appreciate that the information and signals described below may be represented using any of a variety of different technologies and techniques. For example, data, instructions, commands, information, signals, bits, symbols, and chips that may be referenced throughout the description below may be represented by voltages, currents, electromagnetic waves, magnetic fields or particles, optical fields or particles, or any combination thereof, depending in part on the particular application, in part on the desired design, in part on the corresponding technology, etc.

Further, many aspects are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, the sequence(s) of actions described herein can be considered to be embodied entirely within any form of non-transitory computer-readable storage medium having stored therein a corresponding set of computer instructions that, upon execution, would cause or instruct an associated processor of a device to perform the functionality described herein. Thus, the various aspects of the disclosure may be embodied in a number of different forms, all of which have been contemplated to be within the scope of the claimed subject matter. In addition, for each of the aspects described herein, the corresponding form of any such aspects may be described herein as, for example, “logic configured to” perform the described action.

As used herein, the terms “user equipment” (UE) and “base station” are not intended to be specific or otherwise limited to any particular radio access technology (RAT), unless otherwise noted. In general, a UE may be any wireless communication device (e.g., a mobile phone, router, tablet computer, laptop computer, consumer asset tracking device, wearable (e.g., smartwatch, glasses, augmented reality (AR)/virtual reality (VR) headset, etc.), vehicle (e.g., automobile, motorcycle, bicycle, etc.), Internet of Things (IoT) device, etc.) used by a user to communicate over a wireless communications network. A UE may be mobile or may (e.g., at certain times) be stationary, and may communicate with a radio access network (RAN). As used herein, the term “UE” may be referred to interchangeably as an “access terminal” or “AT,” a “client device,” a “wireless device,” a “subscriber device,” a “subscriber terminal,” a “subscriber station,” a “user terminal” or “UT,” a “mobile device,” a “mobile terminal,” a “mobile station,” or variations thereof. Generally, UEs can communicate with a core network via a RAN, and through the core network the UEs can be connected with external networks such as the Internet and with other UEs. Of course, other mechanisms of connecting to the core network and/or the Internet are also possible for the UEs, such as over wired access networks, wireless local area network (WLAN) networks (e.g., based on the Institute of Electrical and Electronics Engineers (IEEE) 802.11 specification, etc.) and so on.

A base station may operate according to one of several RATs in communication with UEs depending on the network in which it is deployed, and may be alternatively referred to as an access point (AP), a network node, a NodeB, an evolved NodeB (eNB), a next generation eNB (ng-eNB), a New Radio (NR) Node B (also referred to as a gNB or gNodeB), etc. A base station may be used primarily to support wireless access by UEs, including supporting data, voice, and/or signaling connections for the supported UEs. In some systems a base station may provide purely edge node signaling functions while in other systems it may provide additional control and/or network management functions. A communication link through which UEs can send signals to a base station is called an uplink (UL) channel (e.g., a reverse traffic channel, a reverse control channel, an access channel, etc.). A communication link through which the base station can send signals to UEs is called a downlink (DL) or forward link channel (e.g., a paging channel, a control channel, a broadcast channel, a forward traffic channel, etc.). As used herein the term traffic channel (TCH) can refer to either an uplink/reverse or downlink/forward traffic channel.

The term “base station” may refer to a single physical transmission-reception point (TRP) or to multiple physical TRPs that may or may not be co-located. For example, where the term “base station” refers to a single physical TRP, the physical TRP may be an antenna of the base station corresponding to a cell (or several cell sectors) of the base station. Where the term “base station” refers to multiple co-located physical TRPs, the physical TRPs may be an array of antennas (e.g., as in a multiple-input multiple-output (MIMO) system or where the base station employs beamforming) of the base station. Where the term “base station” refers to multiple non-co-located physical TRPs, the physical TRPs may be a distributed antenna system (DAS) (a network of spatially separated antennas connected to a common source via a transport medium) or a remote radio head (RRH) (a remote base station connected to a serving base station). Alternatively, the non-co-located physical TRPs may be the serving base station receiving the measurement report from the UE and a neighbor base station whose reference RF signals the UE is measuring. Because a TRP is the point from which a base station transmits and receives wireless signals, as used herein, references to transmission from or reception at a base station are to be understood as referring to a particular TRP of the base station.

In some implementations that support positioning of UEs, a base station may not support wireless access by UEs (e.g., may not support data, voice, and/or signaling connections for UEs), but may instead transmit reference signals to UEs to be measured by the UEs, and/or may receive and measure signals transmitted by the UEs. Such a base station may be referred to as a positioning beacon (e.g., when transmitting signals to UEs) and/or as a location measurement unit (e.g., when receiving and measuring signals from UEs).

An “RF signal” comprises an electromagnetic wave of a given frequency that transports information through the space between a transmitter and a receiver. As used herein, a transmitter may transmit a single “RF signal” or multiple “RF signals” to a receiver. However, the receiver may receive multiple “RF signals” corresponding to each transmitted RF signal due to the propagation characteristics of RF signals through multipath channels. The same transmitted RF signal on different paths between the transmitter and receiver may be referred to as a “multipath” RF signal.

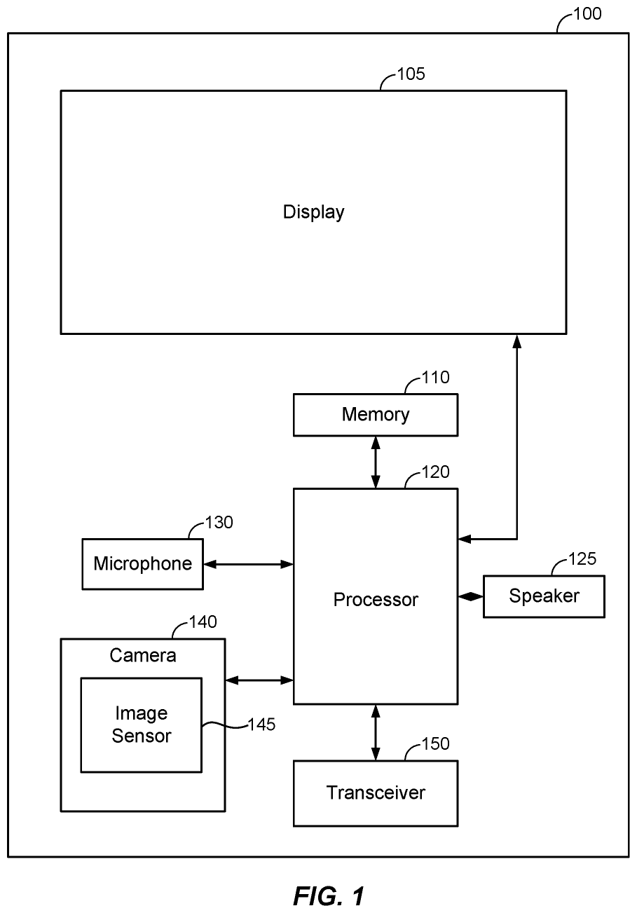

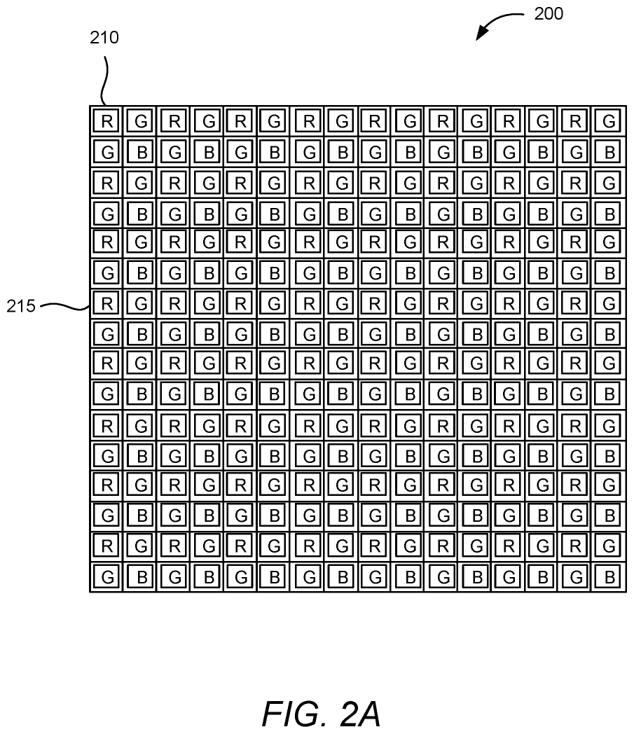

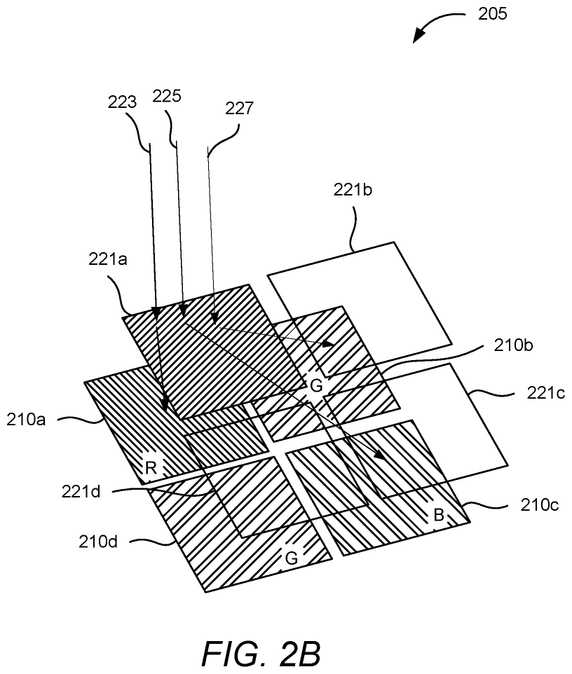

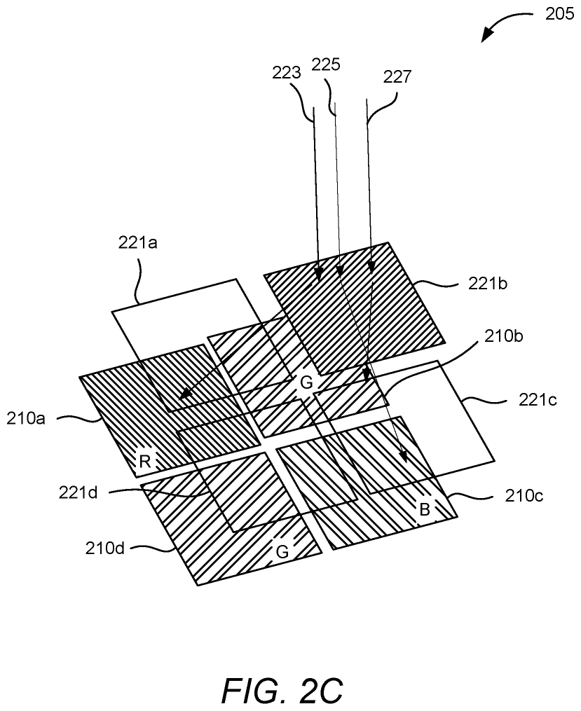

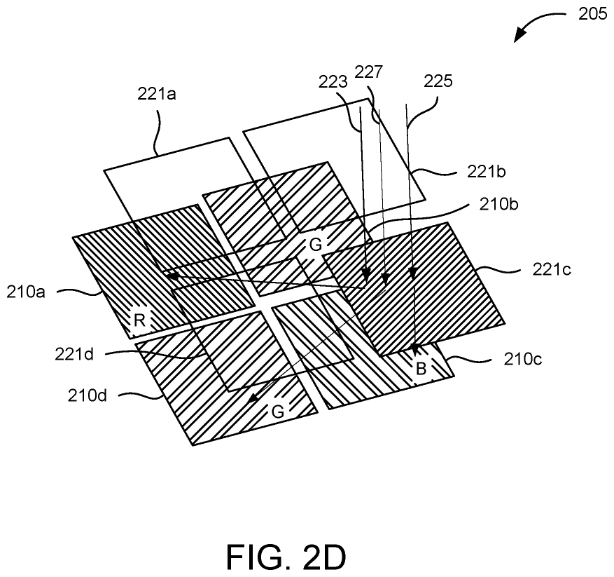

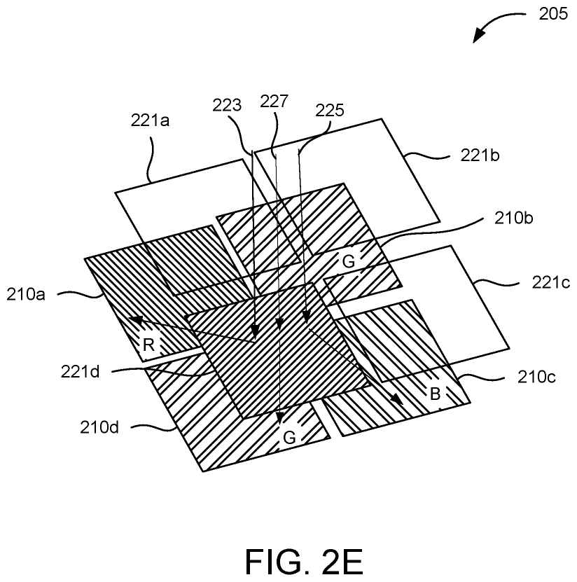

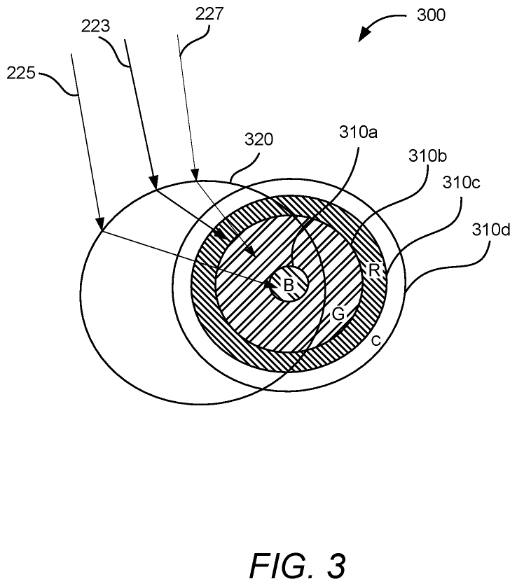

FIG. 1 illustrates an exemplary mobile device 100. In some aspects, mobile device 100 may be considered as a “handset,” a “UE,” an “access terminal” or “AT,” a “client device,” a “wireless device,” a “subscriber device,” a “subscriber terminal,” a “subscriber station,” a “user terminal” or “UT,” a “mobile terminal,” a “mobile station,” or variations thereof. As shown in FIG. 1, mobile device 100 includes a general purpose processor, depicted as processor 120. Processor 120 can be coupled to memory 110. Display 105 can be coupled to processor 120. Transceiver 150 can be coupled to processor 120 and may be configured to receive wireless signals from a calibrated terrestrial source such as WWAN, CDMA, WIFI, etc, and/or satellites or GNSS signals. Furthermore, speaker 125, microphone 130 and camera 140 can be coupled to processor 120. In an aspect, processor 120 may control display 105, speaker 125, microphone 130, transceiver 150 and camera 140. Camera 140 may include image sensor 145. In an aspect, image sensor 145 may comprise image sensor 200 shown in FIG. 2A. In another aspect, image sensor 145 may comprise image sensor 300 shown in FIG. 3.

FIG. 2A is a frontal view of image sensor 200. FIG. 2A shows the structure of image sensor 200. Image sensor 200 includes image capturing pixels 210 forming pixel array 215 as shown in FIG. 2A. In an aspect, the image capturing pixels 210 may be photosensors. Pixels 210 may include red pixels (R), green pixels (G) and blue pixels (B) that may be arranged following the Bayer array pattern rule as shown in FIG. 2A. In an aspect, red pixels (R), green pixels (G) and blue pixels (B) may be arranged and configured to collect and detect red light, green light and blue light, respectively. In an aspect, image sensor 200 further includes an array of lenses (not shown) that overlays pixel array 215, as explained below. The array of lenses may be configured to allow red pixels (R), green pixels (G) and blue pixels (B) to collect and detect red light, green light and blue light, respectively .

FIG. 2B is a diagonal side view of configuration 205 of image sensor 200. FIG. 2B shows configuration 205 that may include pixels 210a, 210b, 210c and 210d arranged following the Bayer array pattern rule in accordance to an aspect. In another aspect, pixels 210a, 210b, 210c and 210d may be arranged in other patterns. In an aspect, configuration 205 may be repeated multiple times to form array 215. In other words, array 215 may be formed by a plurality of image capturing pixels arranged in configuration 205 as shown in FIG. 2A. Pixel 210a is a red pixel (R) for collecting and detecting red light, pixel 210b is a green pixel (G) for collecting and detecting green light, pixel 210c is a blue pixel (B) for collecting and detecting blue light, and pixel 210d is another green pixel (G) for collecting and detecting green light. As shown in FIG. 2B, configuration 205 may further include an array of lenses comprising lenses 221a, 221b, 221c and 221d. In an aspect, lens 221a may overlay red pixel 210a, lens 221b may overlay green pixel 210b, lens 221c may overlay blue pixel 210c and lens 221d may overlay green pixel 210d. This pattern may be repeated all over pixel array 215 where all of the red pixels (R) and blue pixels (B) in pixel array 215 may be overlaid with lenses 221a and 221c, respectively. The green pixels (G) in pixel array 215 may be overlaid with lenses 221b or 221d depending on where a green pixel lands in configuration 205 shown in FIG. 2B. Therefore, in an aspect as shown in FIGS. 2A and 2B, image sensor 200 comprises at least one configuration 205 shown in FIG. 2B. In another aspect, lenses 221a, 221b, 221c and 221d may be arranged in another pattern. In yet another aspect, configuration 205 may have another set of lenses (not shown) in addition to lenses 221a, 221b, 221c and 221d, which may be used to focus lights onto the pixels.

In an aspect, as shown in FIG. 2B, when red light 223 (i.e., the light in visible red spectrum or wavelength) passes through lens 221a, lens 221a may allow red light 223 to pass straight through lens 221a and strike red pixel 210a. When blue light 225 (i.e. the light in visible blue spectrum or wavelength) passes through lens 221a, lens 221a may refract/bend blue light 225 such that blue light 225 strikes blue pixel 210c. When green light 227 (i.e. the light in visible green spectrum or wavelength) passes through lens 221a, lens 221a may refract green light 227 such that green light 227 strikes green pixel 210b.

In an aspect, lenses 221a, 221b, 221c and 221d may be meta lenses that are fabricated using such material as silicon nitride and titanium dioxide. Such meta lenses are able to macroscopically refract or bend lights of certain wavelengths and allow other lights of certain wavelengths to pass through the lenses without refraction. In an aspect, it is noted that meta lenses are not bending light by chromatic aberration but macroscopically bend lights of certain wavelengths. Thus, in an aspect, lenses 221a, 221b, 221c and 221d may refract or bend lights of certain wavelengths macroscopically like a meta lens and not by chromatic aberration. In other aspect, lenses 221a, 221b, 221c and 221d may be fabricated using other materials that are able to macroscopically refract or bend lights of certain wavelengths such that lights of different wavelengths strike their respective pixels on image sensor 200.

FIG. 2C illustrates another exemplary operation of image sensor 200. As shown in FIG. 2C, when green light 227 passes through lens 221b, lens 221b may allow green light 227 to pass straight through lens 221b and strike green pixel 210b. When blue light 225 passes through lens 221b, lens 221b may refract/bend blue light 225 such that blue light 225 strikes blue pixel 210c. When red light 223 passes through lens 221b, lens 221b may refract/bend red light 223 such that red light 223 strikes red pixel 210a.

FIG. 2D illustrates another exemplary operation of image sensor 200. As shown in FIG. 2D, when blue light 225 passes through lens 221c, lens 221c may allow blue light 225 to pass straight through lens 221c and strike blue pixel 210c. When green light 227 passes through lens 221c, lens 221c may refract/bend green light 227 such that green light 227 strikes green pixel 210d. When red light 223 passes through lens 221c, lens 221c may refract/bend red light 223 such that red light 223 strikes red pixel 210a.

FIG. 2E illustrates another exemplary operation of image sensor 200. As shown in FIG. 2E, when green light 227 passes through lens 221d, lens 221d may allow green light 227 to pass straight through lens 221d and strike green pixel 210d. When blue light 225 passes through lens 221d, lens 221d may refract/bend blue light 225 such that blue light 225 strikes blue pixel 210c. When red light 223 passes through lens 221d, lens 221d may refract/bend red light 223 such that red light 223 strikes red pixel 210a.

In an aspect, lenses 221a, 221b, 221c and 221d in configuration 205 allow for more lights to strike pixels 210a, 210b, 210c and 210d by refracting lights onto the pixels instead of filtering lights.

FIG. 3 is a frontal view of image sensor 300 in accordance with another aspect. As shown in FIG. 3, image sensor 300 includes pixels 310a, 310b, 310c and 310d arranged in concentric circle formation. In an aspect, pixels 310a, 310b, 310c and 310d may have a common center. Pixel 310c is a red pixel (R) for collecting and detecting red light, pixel 310b is a green pixel (G) for collecting and detecting green light, pixel 310a is a blue pixel (B) for collecting and detecting blue light, and pixel 310d is a clear pixel (C) for collecting and detecting infrared lights. In an aspect, clear pixel 310d may be used to capture light in low light environment such that the image captured by pixel 310d may be fused with the image captured by other pixels to derive a better image, especially in low light environment. In an aspect, clear pixel 310d may be used to determine the amount light received by image sensor 300. As shown in FIG. 3, image sensor 300 further includes lens 320. In an aspect, lens 320 may overlay red pixel 310c, green pixel 310b, blue pixel 310a and clear pixel 310d. In an aspect, the area of green pixel 310b may be twice the area of blue pixel 310a or red pixel 310c such that:

Area of green pixel 310b=π*(r2−r1)²=2*blue pixel 310a=2*red pixel 310c,
where r2=radius of green pixel 310b from the center and r1=radius of blue pixel 310a from the center.

In an aspect, image sensor 300 may comprise an array of concentric pixels 310a, 310b, 310c and 310d similar to array 215 shown in FIG. 2A. Image sensor 300 may further comprise an array of lenses 320 that overlay the array of concentric pixels 310a, 310b, 310c and 310d. In an aspect, as shown in FIG. 3, lens 320 may refract/bend blue light 225 to strike blue pixel 310a, green light 227 to strike green pixel 310b, red light 223 to strike red pixel 310c and infrared light to strike clear pixel 310d.

In an aspect, lens 320 may be a meta lens that is fabricated using such material as silicon nitride and titanium dioxide. Such meta lenses are able to macroscopically refract or bend lights of certain wavelengths and allow other lights of certain wavelengths to pass through the lenses without refraction. Thus, in an aspect, lens 320 may refract or bend lights of certain wavelengths macroscopically like a meta lens. In other aspect, lens 320 may be fabricated using other materials that are able to macroscopically refract or bend lights of certain wavelengths such that lights of different wavelengths land on their respective pixels on image sensor 300. In an aspect, since pixels 310a, 310b, 310c and 310d are centered together, image sensor 300 may allow for more efficient or easier processing by an image processor (not shown) later.

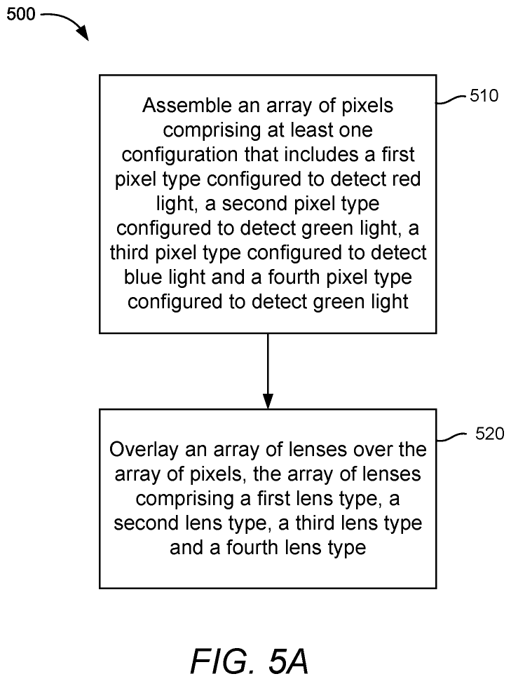

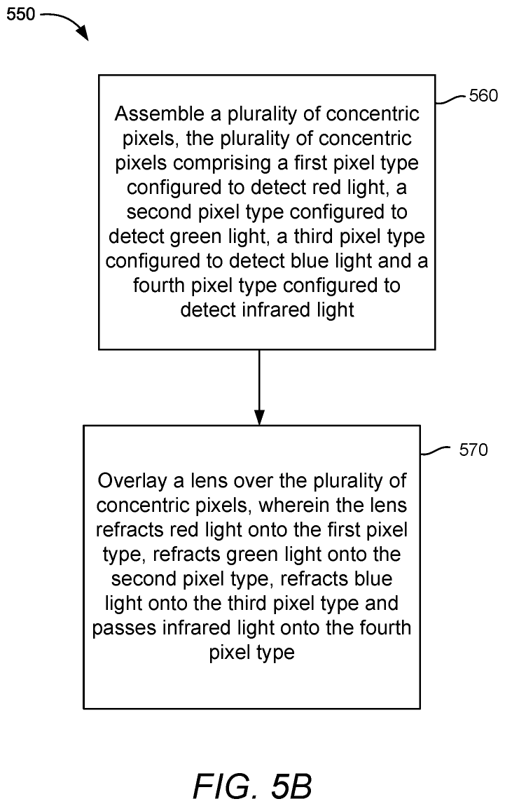

It will be appreciated that aspects include various methods for performing the processes, functions and/or algorithms disclosed herein. For example, FIGS. 5A-5B show methods 500 and 550 for fabricating an image sensor with macroscopically refracting lens in accordance to one aspect.

At block 510, the method 500 assembles an array of image capturing pixels. The image capturing pixels may comprise pixels 210 that includes red pixels (R), green pixels (G) and blue pixels (B). In an aspect, pixels 210 may be arranged in the Bayer array pattern like pixel array 215 as shown in FIG. 2A. In another aspect, pixels 210 may be arranged in other patterns.

At block 520, the method 500 overlays an array of lenses over the array of image capturing pixels. The array of lenses may comprise lenses 221a, 221b, 221c and 221d. All of the red pixels (R) and blue pixels (B) in pixel array 215 may be overlaid with lenses 221a and 221c, respectively. The green pixels (G) in pixel array 215 may be overlaid with lenses 221b or 221d depending on where a green pixel lands in the pattern shown in FIG. 2B.

At block 560, the method 550 assembles concentric image capturing pixels. The concentric image capturing pixels may comprise pixels 310a, 310b, 310c and 310d arranged in concentric circle formation as shown in FIG. 3. Pixel 310c is a red pixel (R) for collecting and detecting red light, pixel 310b is a green pixel (G) for collecting and detecting green light, pixel 310a is a blue pixel (B) for collecting and detecting blue light, and pixel 310d is a clear pixel (C) for collecting and detecting infrared lights.

At block 570, the method 550 overlays a lens over the concentric pixels. The lens may be lens 320 that overlays concentric pixels 310a, 310b, 310c and 310d as shown in FIG. 3. As shown in FIG. 3, lens 320 may refract/bend blue light 225 to strike blue pixel 310a, green light 227 to strike green pixel 310b, red light 223 to strike red pixel 310c and infrared light to strike clear pixel 310d.

In the detailed description above it can be seen that different features are grouped together in examples. This manner of disclosure should not be understood as an intention that the example clauses have more features than are explicitly mentioned in each clause. Rather, the various aspects of the disclosure may include fewer than all features of an individual example clause disclosed. Therefore, the following clauses should hereby be deemed to be incorporated in the description, wherein each clause by itself can stand as a separate example. Although each dependent clause can refer in the clauses to a specific combination with one of the other clauses, the aspect(s) of that dependent clause are not limited to the specific combination. It will be appreciated that other example clauses can also include a combination of the dependent clause aspect(s) with the subject matter of any other dependent clause or independent clause or a combination of any feature with other dependent and independent clauses. The various aspects disclosed herein expressly include these combinations, unless it is explicitly expressed or can be readily inferred that a specific combination is not intended (e.g., contradictory aspects, such as defining an element as both an insulator and a conductor). Furthermore, it is also intended that aspects of a clause can be included in any other independent clause, even if the clause is not directly dependent on the independent clause.

Implementation examples are described in the following numbered clauses:

Clause 1. An image sensor comprising: an array of pixels, the array of pixels comprising

at least one configuration that includes a first pixel type configured to detect red light, a second pixel type configured to detect green light, a third pixel type configured to detect blue light and a fourth pixel type configured to detect green light; and an array of lenses overlaying the array of pixels, the array of lenses comprising a first lens type, a second lens type, a third lens type and a fourth lens type, wherein the first lens type is configured to pass red light and refract blue light and green light, the second lens type is configured to pass green light and refract blue light and red light, the third lens type is configured to pass blue light and refract red light and green light, and the fourth lens type is configured to pass green light and refract blue light and red light.

Clause 2. The image sensor of clause 1, wherein the at least one configuration follows a Bayer array pattern rule.

Clause 3. The image sensor of any of clauses 1 to 2, wherein the first lens type overlays the first pixel type, the second lens type overlays the second pixel type, the third lens type overlays the third pixel type, and the fourth lens type overlays the fourth pixel type.

Clause 4. The image sensor of clause 3, wherein the first lens type refracts blue light onto the third pixel type and refracts green light onto the second pixel type.

Clause 5. The image sensor of clause 4, wherein the second lens type refracts red light onto the first pixel type and refracts blue light onto the third pixel type.

Clause 6. The image sensor of clause 5, wherein the third lens type refracts red light onto the first pixel type and refracts green light onto the fourth pixel type.

Clause 7. The image sensor of clause 6, wherein the fourth lens type refracts blue light onto the third pixel type and refracts red light onto the first pixel type.

Clause 8. The image sensor of any of clauses 1 to 7, wherein the lenses are made of meta material.

Clause 9. A method of fabricating an image sensor, the method comprising: assembling an array of pixels comprising at least one configuration that includes a first pixel type configured to detect red light, a second pixel type configured to detect green light, a third pixel type configured to detect blue light and a fourth pixel type configured to detect green light; and overlaying an array of lenses over the array of pixels, the array of lenses comprising a first lens type, a second lens type, a third lens type and a fourth lens type, wherein: the first lens type is configured to pass red light and refract blue light and green light, the second lens type is configured to pass green light and refract blue light and red light, the third lens type is configured to pass blue light and refract red light and green light, and the fourth lens type is configured to pass green light and refract blue light and red light.

Clause 10. The method of clause 9, wherein the at least one configuration follows a Bayer array pattern rule.

Clause 11. The method of any of clauses 9 to 10, wherein the first lens type overlays the first pixel type, the second lens type overlays the second pixel type, the third lens type overlays the third pixel type, and the fourth lens type overlays the fourth pixel type.

Clause 12. The method of clause 11, wherein the first lens type refracts blue light onto the third pixel type and refracts green light onto the second pixel type.

Clause 13. The method of clause 12, wherein the second lens type refracts red light onto the first pixel type and refracts blue light onto the third pixel type.

Clause 14. The method of clause 13, wherein the third lens type refracts red light onto the first pixel type and refracts green light onto the fourth pixel type.

Clause 15. The method of clause 14, wherein the fourth lens type refracts blue light onto the third pixel type and refracts red light onto the first pixel type.

Clause 16. The method of any of clauses 9 to 15, wherein the lenses are fabricated using meta material.

Clause 17. An image sensor comprising: means for detecting lights, the means for detecting lights comprising at least one configuration that includes a first pixel type configured to detect red light, a second pixel type configured to detect green light, a third pixel type configured to detect blue light and a fourth pixel type configured to detect green light; and means for refracting lights, the means for refracting lights comprising a first lens type, a second lens type, a third lens type and a fourth lens type, wherein: the first lens type is configured to pass red light and refract blue light and green light, the second lens type is configured to pass green light and refract blue light and red light, the third lens type is configured to pass blue light and refract red light and green light, and the fourth lens type is configured to pass green light and refract blue light and red light.

Clause 18. The image sensor of clause 17, wherein the at least one configuration follows a Bayer array pattern rule.

Clause 19. The image sensor of any of clauses 17 to 18, wherein the first lens type overlays the first pixel type, the second lens type overlays the second pixel type, the third lens type overlays the third pixel type, and the fourth lens type overlays the fourth pixel type.

Clause 20. The image sensor of clause 19, wherein the first lens type refracts blue light onto the third pixel type and refracts green light onto the second pixel type.

Clause 21. The image sensor of clause 20, wherein the second lens type refracts red light onto the first pixel type and refracts blue light onto the third pixel type.

Clause 22. The image sensor of clause 21, wherein the third lens type refracts red light onto the first pixel type and refracts green light onto the fourth pixel type.

Clause 23. The image sensor of clause 22, wherein the fourth lens type refracts blue light onto the third pixel type and refracts red light onto the first pixel type.

Clause 24. The image sensor of any of clauses 17 to 23, wherein the means for refracting lights are made of meta material.

Clause 25. An image sensor comprising: a plurality of concentric pixels, the plurality of concentric pixels comprising a first pixel type configured to detect red light, a second pixel type configured to detect green light, a third pixel type configured to detect blue light and a fourth pixel type configured to detect infrared light; and a lens overlaying the plurality of concentric pixels, wherein the lens refracts red light onto the first pixel type, refracts green light onto the second pixel type, refracts blue light onto the third pixel type and passes infrared light onto the fourth pixel type.

Clause 26. The image sensor of clause 25, wherein the fourth pixel type measures the amount of lights received by the plurality of pixels.

Clause 27. The image sensor of any of clauses 25 to 26, wherein the lens is a meta lens.

Clause 28. The image sensor of any of clauses 25 to 27, wherein the second pixel type is larger than the first and third pixel types.

Clause 29. A method of fabricating an image sensor, the method comprising: assembling a plurality of concentric pixels, the plurality of concentric pixels comprising a first pixel type configured to detect red light, a second pixel type configured to detect green light, a third pixel type configured to detect blue light and a fourth pixel type configured to detect infrared light; and overlaying a lens over the plurality of concentric pixels, wherein the lens refracts red light onto the first pixel type, refracts green light onto the second pixel type, refracts blue light onto the third pixel type and passes infrared light onto the fourth pixel type.

Clause 30. The method of clause 29, wherein the fourth pixel type measures the amount of lights received by the plurality of pixels.

Clause 31. The method of clause 30, wherein the lens is a meta lens.

Clause 32. The method of clause 31, wherein the second pixel type is larger than the first and third pixel types.

Clause 33. An image sensor comprising: means for detecting lights, the means for detecting lights comprising a plurality of concentric pixels, the plurality of concentric pixels including a first pixel type configured to detect red light, a second pixel type configured to detect green light, a third pixel type configured to detect blue light and a fourth pixel type configured to detect infrared light; and means for refracting lights, the means for refracting lights comprising a lens overlaying the plurality of concentric pixels, wherein the lens refracts red light onto the first pixel type, refracts green light onto the second pixel type, refracts blue light onto the third pixel type and passes infrared light onto the fourth pixel type.

Clause 34. The image sensor of clause 33, wherein the fourth pixel type measures the amount of lights received by the plurality of pixels.

Clause 35. The image sensor of any of clauses 33 to 34, wherein the lens is a meta lens.

Clause 36. The image sensor of any of clauses 33 to 35, wherein the second pixel type is larger than the first and third pixel types.

Clause 37. An apparatus comprising a memory, a transceiver, and a processor communicatively coupled to the memory and the transceiver, the memory, the transceiver, and the processor configured to perform a method according to any of clauses 1 to 36.

Clause 38. An apparatus comprising means for performing a method according to any of clauses 1 to 36.

Clause 39. A non-transitory computer-readable medium storing computer-executable instructions, the computer-executable comprising at least one instruction for causing a computer or processor to perform a method according to any of clauses 1 to 36.

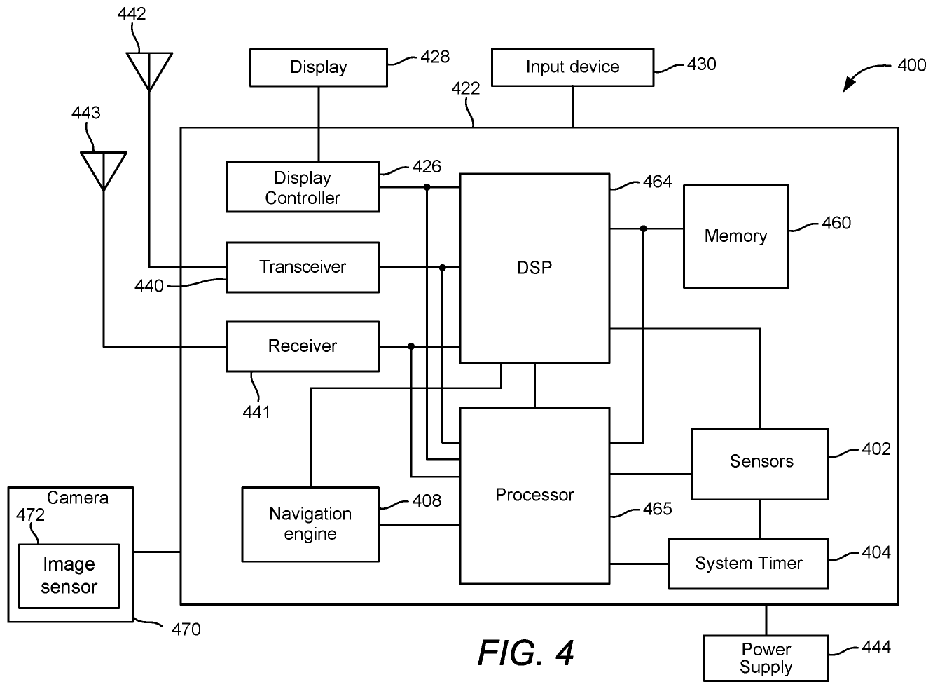

With reference now to FIG. 4, another exemplary device 400 implemented as a wireless communication device is illustrated. Device 400 is similar to mobile device 100 in many exemplary aspects, and the depiction and description of device 400 includes various additional exemplary components not shown with relation to mobile device 100 shown in FIG. 1. As shown in FIG. 4, device 400 includes digital signal processor (DSP) 464 and a general purpose processor, depicted as processor 465. Both DSP 464 and processor 465 may be coupled to memory 460. Navigation engine 408 can be coupled to DSP 464 and processor 465 and used to provide location data to DSP 464 and processor 465. Sensors 402 may include sensors such as gyroscope and accelerometer. Display controller 426 can be coupled to DSP 464, processor 465, and to display 428. Other components, such as transceiver 440 (which may be part of a modem) and receiver 441 are also illustrated. Transceiver 440 can be coupled to antenna array 442, which may be configured to receive wireless signals from a calibrated terrestrial source such as WWAN, CDMA, etc. Receiver 441 can be coupled to a satellite or GNSS antenna 443, which may be configured to receive wireless signals from satellites or GNSS signals. System timer 404 is also illustrated and may provide timing signals to DSP 464 and processor 465 to determine time of the day or other time related data. In a particular aspect, DSP 464, processor 465, display controller 426, memory 460, navigation engine 408, transceiver 440, receiver 441, sensors 402, and system timer 404 are included in a system-in-package or system-on-chip device 422.

In a particular aspect, input device 430 and power supply 444 are coupled to the system-on-chip device 422. In an aspect, camera 470 is coupled to the system-on-chip device 422. Camera 470 includes image sensor 472. In a particular aspect, image sensor 472 may comprise image sensor 200. In another aspect, image sensor 472 may comprise image sensor 300. Moreover, in a particular aspect, as illustrated in FIG. 4, display 428, input device 430, antenna array 442, GNSS antenna 443, camera 470 and power supply 444 are external to the system-on-chip device 422. However, each of display 428, input device 430, antenna array 442, GNSS antenna 443, camera 470 and power supply 444 can be coupled to a component of the system-on-chip device 422, such as an interface or a controller.

It should be noted that although FIG. 4 depicts a wireless communications device, DSP 464, processor 465, and memory 460 may also be integrated into a device, selected from the group consisting of a set-top box, a music player, a video player, an entertainment unit, a navigation device, a communications device, a personal digital assistant (PDA), a fixed location data unit, or a computer. Moreover, such a device may also be integrated in a semiconductor die.

Accordingly it will be appreciated from the foregoing that at least one aspect includes an image sensor that comprises: an array of pixels, the array of pixels comprising at least one configuration that includes a first pixel type configured to detect red light, a second pixel type configured to detect green light, a third pixel type configured to detect blue light and a fourth pixel type configured to detect green light; and an array of lenses overlaying the array of pixels, the array of lenses comprising a first lens type, a second lens type, a third lens type and a fourth lens type, wherein: the first lens type is configured to pass red light and refract blue light and green light, the second lens type is configured to pass green light and refract blue light and red light, the third lens type is configured to pass blue light and refract red light and green light, and the fourth lens type is configured to pass green light and refract blue light and red light.

In another aspect, an image sensor comprises: a plurality of concentric pixels, the plurality of concentric pixels comprising a first pixel type configured to detect red light, a second pixel type configured to detect green light, a third pixel type configured to detect blue light and a fourth pixel type configured to detect infrared light; and a lens overlaying the plurality of concentric pixels, wherein the lens refracts red light onto the first pixel type, refracts green light onto the second pixel type, refracts blue light onto the third pixel type and passes infrared light onto the fourth pixel type.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a general purpose processor, a DSP, an ASIC, an FPGA, or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The methods, sequences and/or algorithms described in connection with the aspects disclosed herein may be embodied directly in hardware, in a software module executed by a processor, or in a combination of the two. A software module may reside in random access memory (RAM), flash memory, read-only memory (ROM), erasable programmable ROM (EPROM), electrically erasable programmable ROM (EEPROM), registers, hard disk, a removable disk, a CD-ROM, or any other form of storage medium known in the art. An example storage medium is coupled to the processor such that the processor can read information from, and write information to, the storage medium. In the alternative, the storage medium may be integral to the processor. The processor and the storage medium may reside in an ASIC. The ASIC may reside in a user terminal (e.g., UE). In the alternative, the processor and the storage medium may reside as discrete components in a user terminal.

In one or more example aspects, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

While the foregoing disclosure shows illustrative aspects of the disclosure, it should be noted that various changes and modifications could be made herein without departing from the scope of the disclosure as defined by the appended claims. The functions, steps and/or actions of the method claims in accordance with the aspects of the disclosure described herein need not be performed in any particular order. Furthermore, although elements of the disclosure may be described or claimed in the singular, the plural is contemplated unless limitation to the singular is explicitly stated.

What is claimed is:

1. An image sensor comprising:
a plurality of concentric pixels, the plurality of concentric pixels comprising a first pixel type configured to detect red light, a second pixel type configured to detect green light, a third pixel type configured to detect blue light and a fourth pixel type configured to detect infrared light; and
a lens overlaying the plurality of concentric pixels, wherein the lens refracts red light onto the first pixel type, refracts green light onto the second pixel type, refracts blue light onto the third pixel type and passes infrared light onto the fourth pixel type.

2. The image sensor of claim 1, wherein the fourth pixel type measures the amount of lights received by the plurality of pixels.

3. The image sensor of claim 1, wherein the lens is a meta lens.

4. The image sensor of claim 1, wherein the second pixel type is larger than the first and third pixel types.

5. A method of fabricating an image sensor, the method comprising:
assembling a plurality of concentric pixels, the plurality of concentric pixels comprising a first pixel type configured to detect red light, a second pixel type configured to detect green light, a third pixel type configured to detect blue light and a fourth pixel type configured to detect infrared light; and
overlaying a lens over the plurality of concentric pixels, wherein the lens refracts red light onto the first pixel type, refracts green light onto the second pixel type, refracts blue light onto the third pixel type and passes infrared light onto the fourth pixel type.

6. The method of claim 5, wherein the fourth pixel type measures the amount of lights received by the plurality of pixels.

7. The method of claim 5, wherein the lens is a meta lens.

8. The method of claim 5, wherein the second pixel type is larger than the first and third pixel types.

9. An image sensor comprising:
means for detecting lights, the means for detecting lights comprising a plurality of concentric pixels, the plurality of concentric pixels including a first pixel type configured to detect red light, a second pixel type configured to detect green light, a third pixel type configured to detect blue light and a fourth pixel type configured to detect infrared light; and
means for refracting lights, the means for refracting lights comprising a lens overlaying the plurality of concentric pixels, wherein the lens refracts red light onto the first pixel type, refracts green light onto the second pixel type, refracts blue light onto the third pixel type and passes infrared light onto the fourth pixel type.

10. The image sensor of claim 9, wherein the fourth pixel type measures the amount of lights received by the plurality of pixels.

11. The image sensor of claim 9, wherein the lens is a meta lens.

12. The image sensor of claim 9, wherein the second pixel type is larger than the first and third pixel types.
